(19) United States
(12) Patent Application Publication
(10) Pub. No.: US 2011/0254138 A1
(43) Pub. Date: Oct. 20, 2011

(54) LOW-TEMPERATURE ABSORBER FILM AND METHOD OF FABRICATION

(75) Inventors: Katherina E. Babich, Chappaqua, NY (US); Pratik P. Joshi, Cliffside Park, NJ (US); Kam Leung Lee, Putnam Valley, NY (US); Deborah A. Neumayer, Danbury, CT (US); Spyridon Skordas, Wappingers Falls, NY (US)

(73) Assignee: INTERNATIONAL BUSINESS MACHINES CORPORATION, Armonk, NY (US)

(21) Appl. No.: 12/760,620

(22) Filed: Apr. 15, 2010

(51) Int. Cl. H01L 23/00; F21V 9/00; H01L 21/321

(52) U.S. Cl. 257/629; 438/758; 252/582; 257/E23.002; 257/E21.3

(57) ABSTRACT

An improved low-temperature absorber, amorphous carbonitride (ACN) with an extinction coefficient (k) of greater than 0.15, and an emissivity of greater than 0.8 is disclosed. The ACN film can also be characterized as having a minimum of hydrocarbon content as observed by FTIR. The ACN film can be used as an effective absorbing layer that absorbs a wide range of electromagnetic radiation from different sources including lasers or flash lamps. A method of forming such an ACN film at a deposition temperature of less than, or equal to, 450° C. is also provided.

### BACKGROUND

The present invention relates to an improved low-temperature absorber film and a method of fabricating such a low-temperature absorber film. More specifically, the invention provides an amorphous carbonitride film having improved absorption properties which can be exposed to electromagnetic radiation that has one or more wavelengths between 190 nm and 1000 nm.

Rapid thermal processing (RTP) is commonly used during fabrication of integrated circuits (ICs) for deposition of layers, or to anneal previously deposited layers. For example, fabrication of ultra-shallow junctions requires a minimal overall thermal budget. Instead of RTP, the activation of dopants can be achieved by a rapid laser annealing process or by flash anneals with high intensity lamps.

As described in U.S. Pat. Nos. 7,109,087 and 7,262,106, an absorbing layer of amorphous carbon is typically deposited on top of a material or device to be annealed in order to get adequate and uniform laser energy absorption. These prior art amorphous carbon absorbing layers are used in conjunction with laser anneals to improve heating uniformity across a plurality of surfaces, and devices during IC fabrication. As described in the aforementioned publications, laser anneals have the advantage of not heating the entire thickness of the substrate, which limits the amount of time that a substrate is exposed to elevated temperatures thus minimizing unwanted diffusion of dopants in the substrate and substrate damage.

One potential drawback with prior art amorphous carbon layers is that they lack sufficient absorptivity when deposited at temperatures less than 450° C., because of incorporation of excess amounts of hydrocarbon which reduces absorptivity. Another potential drawback with prior art amorphous carbon layers is that the prior art amorphous carbon layers are highly transparent and thus they exhibit a high reflectance variations from the substrate.

### SUMMARY

An improved absorber film deposited at temperatures less than 450° C. is provided that has a high absorptivity and is less transparent than prior art amorphous carbon absorber films deposited at comparable temperatures. The improved absorber film disclosed herein is a thinner film than typical prior art amorphous carbon only layers and, in some embodiments, the improved absorber film can be exposed to electromagnetic radiation that has one or more wavelengths between 190 nm and 1000 nm. More particularly, the present invention provides an amorphous carbonitride (ACN) film that can be deposited at a temperature of less than, or equal to, 450° C. The amorphous carbonitride film deposited at such a low-temperature has an extinction coefficient (k) of greater than 0.15, an emissivity of greater than 0.8, and a minimum of hydrocarbon content as observed by FTIR.

The term “amorphous” when used in conjunction with the carbonitride film denotes that the carbonitride film lacks a well defined crystal structure. Moreover, while there may be local ordering of the atoms or molecules in the amorphous carbonitride film, no long-term ordering is present. By “minimum of hydrocarbon content as observed by FTIR” it is meant a normalized hydrocarbon content less than 3 as defined by integrating under the C—H stretching peak in the FTIR spectra from 3170-2750 cm⁻¹ and dividing the integrated peak area by the film thickness in microns.

A high extinction coefficient and/or emissivity are indicative of greater absorptivity of the film, and less transparency which minimizes reflectance variations from the substrate. Additionally, the amorphous carbonitride (ACN) film can be optimized to possess minimal stress in order to avoid delamination during deposition, and anneals.

The applicants of the present invention have discovered through extensive experimentation that by reducing the hydrocarbon content in the film one can increase the extinction coefficient and thus increase the absorptivity of the film. Reduced hydrocarbon content has the additional benefit of minimizing the outgassing during anneals, and increasing the tool life as evidenced by a film shrinkage of less than 15% after a 1000° C., 1 minute anneal in N₂.

In one aspect of the invention, an improved absorber film comprising, consisting essentially of, or consisting of, amorphous carbonitride is provided that has superior absorbing properties than existing absorbing films. The improved amorphous carbonitride film has an extinction coefficient (k) of greater than 0.15, and an emissivity of greater than 0.8 and a minimum of hydrocarbon content as observed by FTIR.

In another aspect of the invention, a method of forming such an amorphous carbonitride film is provided that includes a low-temperature deposition process. By “low-temperature”, it is meant a deposition process that is performed at a deposition temperature of less than, or equal to 450° C.

In one embodiment of the invention, an improved absorber film having at least an extinction coefficient (k) of greater than 0.15, and an emissivity of greater than 0.8 can be deposited by plasma enhanced chemical vapor deposition (PECVD) by introducing a carbon precursor source, an oxidant and a nitrogen source into a reactor chamber including a substrate. The introduction of the carbon precursor source, oxidant and nitrogen source produces amorphous carbonitride films of the desired properties at deposition temperatures of less than, or equal to 450° C.

In another embodiment of the invention, an amorphous carbonitride film can be deposited by plasma enhanced chemical vapor deposition (PECVD) by introducing a carbon precursor source, and a nitrogen source without an oxidant into a reactor chamber including a substrate. The introduction of the carbon precursor source and nitrogen source, without the oxidant, produces amorphous carbonitride films of the desired properties at deposition temperatures of less than, or equal to 450° C.

In yet another embodiment of the invention, an amorphous carbonitride film can be deposited by plasma enhanced chemical vapor deposition (PECVD) by introducing a single carbonitride precursor with both carbon and nitrogen in the molecule, into a reactor chamber including a substrate. The introduction of the single carbonitride precursor produces amorphous carbonitride films of the desired properties at deposition temperatures of less than, or equal to 450° C.

In still another embodiment of the invention, an amorphous carbonitride film can be deposited by plasma enhanced chemical vapor deposition (PECVD) by introducing a single carbonitride precursor with both carbon and nitrogen in the molecule and an oxidant, into a reactor chamber including a substrate. The introduction of the single carbonitride precursor and an oxidant produces amorphous carbonitride films of the desired properties at deposition temperatures of less than, or equal to 450° C.

The improved ACN films disclosed herein can provide adequate laser energy absorption properties and can have the advantage of a minimum of inherent hydrocarbon content (a normalized hydrocarbon content less than 3 as defined by integrating under the C—H stretching peak in the FTIR spectra from 3170-2750 cm⁻¹ and dividing the integrated peak area by the film thickness in microns.). Reduced hydrocarbon content improves film opacity, and minimizes outgassing during laser and arc anneals, which is highly desirable.

### BRIEF DESCRIPTION OF THE DRAWINGS

FIG. 1 is a graph illustrating the preamorphized silicon re-growth rate as a function of temperature.

FIG. 2 includes FTIR spectra of prior art amorphous carbon only films deposited at 550° C., 480° C. and 400° C.

FIG. 3 is a pictorial representation (through a cross sectional view) depicting an amorphous carbonitride film having an extinction coefficient of greater than 0.15, an emissivity of greater than 0.8 and a low hydrocarbon content on a surface of a substrate in accordance with an embodiment of the invention.

FIG. 4 is a pictorial representation (through a cross sectional view) depicting a structure including a substrate having amorphous carbonitride films deposited on adhesion promoting layers in accordance with an embodiment of the invention.

FIG. 5 includes a plot of R_{S} measurements performed on amorphous carbon only layers (ACL; prior art) and amorphous carbonitride (ACN; invention) films.

FIG. 6 includes FTIR spectra of Samples 1, 2, 3 and 4 from Table 5 of the present application.

FIG. 7 is an SEM micrograph showing an intact amorphous carbonitride film after flash anneal at 1300° C. in accordance with one embodiment of the invention.

FIG. 8 is a plot of wavelength (nm) vs. reflectivity (%) for various samples including an SOI substrate with no absorber coating, an SOI substrate with a prior art amorphous carbon only absorber coating, and amorphous carbonitride absorber coating in accordance with the invention.

FIG. 9 is a plot of energy set point (kJ) vs. front surface temperature jump (° C.) for SOI substrates with an absorber coating and without an absorber coating.

FIG. 10 is a plot of flash annealing (intermediate temperature Tᵢ-peak temperature Tₚ) vs. % implanted carbon in Si in the source/drain regions of an NFET within Example 7.

FIG. 11 is a plot of flash annealing (intermediate temperature Tᵢ-peak temperature Tₚ) vs. SiC S/D sheet resistivity (ohm/square) for various samples within Example 7.

### DETAILED DESCRIPTION

The present invention, which provides a low-temperature amorphous carbonitride (ACN) absorbing film, will now be described in greater detail by referring to the following discussion and drawings that accompany the present application. It is noted that the drawings of the present application are provided for illustrative purposes only and, as such, the drawings are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

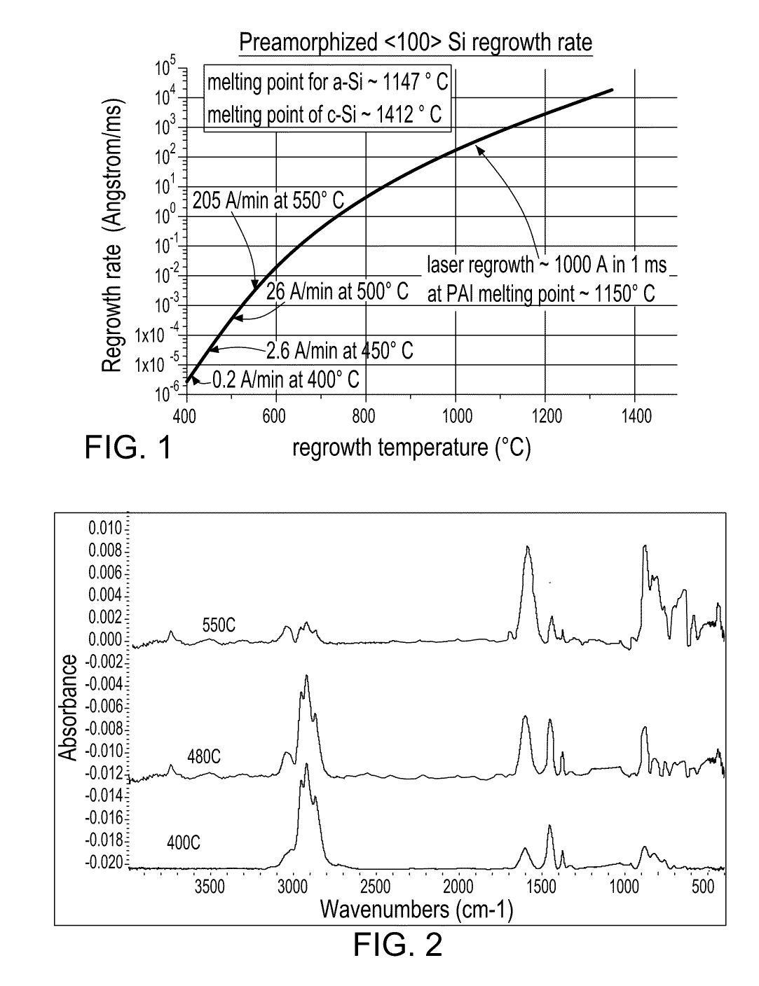

Before discussing the present invention in greater detail, the applicants determined through experimentation that in order to achieve a sufficient amorphous carbon only absorbent film, as defined by a k greater than 0.15, an emissivity of about 0.8 or greater, and a film with a minimum of hydrocarbon in it as observed by FTIR, it was necessary to deposit an amorphous carbon only layer (ACL) at 550° C. This is undesirable as the constantly shrinking sizes of transistors put an unavoidable limitation on the processing temperatures of devices. When scaling down the dimensions of metal oxide semiconductor field effect transistor (MOSFET) devices, ultra-shallow contacts and extremely abrupt junctions between the source/drain electrodes and the channel are needed in order to suppress short channel effects. At the same time, the source/drain contacts must be highly doped to keep parasitic resistances as small as possible. Current MOSFET fabrication schemes employ ion implantation for the amorphization and subsequent dopant introduction into a silicon crystal lattice. Silicon amorphization reduces dopant atom channeling during implantation, thereby allowing ultra-shallow junction formation. Although ion implantation offers a number of advantages, the inherent damage to the crystal lattice structure contributes to the mobility degradation in the final device structures. Lattice repair via the application of an annealing step is thus essential. The applicants of the present disclosure have discovered that preamorphized silicon (PAI) regrowth during deposition of the amorphous carbon layer at 550° C. (Sample 1, Table 1) hinders dopant activation at higher subsequent anneals. During the ACL deposition process, the PAI growth rate for implanted wafers is very significant. FIG. 1 shows PAI re-growth rate as a function of temperature. At deposition temperatures of greater than 400° C., PAI regrowth was observed and at 550° C. deposition temperature PAI re-growth rate was approximately 205 Å/min. This hinders dopant activation if PAI is regrown at a much higher temperature (greater than 1000° C.) during laser or flash anneals. Therefore, some of the device schemes can not use absorbing layers deposited at temperatures of greater than 400° C., as it promotes implant diffusion, increases junction surface resistance/interface reaction, and re-growth of high k oxide interfaces.

One potential solution is to lower the deposition temperature of amorphous carbon only films, however as the deposition temperature of the amorphous carbon only films was decreased below 550° C., hydrocarbon content in the film increased rapidly which reduced the absorptive capabilities of the film, k was reduced and emissivity was reduced. As detailed in Table 1, the normalized hydrocarbon content rapidly increases as the deposition temperature is reduced from 550° C. to 480° C. and 400° C. As summarized in Table 1, the k decreased with lower deposition temperature.

TABLE 1
Deposition Conditions and extinction coefficient
(k) values for amorphous carbon only films

| | | | | | | | CH peak |
|---|---|---|---|---|---|---|---|
| | Temper- | | | | | | area/ |
| | ature | Pressure | HFRF | C₃H₆ | He | | thickness |
| Sample | (° C.) | (torr) | (watts) | (sccm) | (sccm) | k | (μm) |
| 1 | 550 | 6 | 785 | 600 | 325 | 0.51 | 1 |
| 2 | 480 | 6 | 785 | 600 | 325 | 0.14 | 4 |
| 3 | 400 | 6 | 785 | 600 | 325 | 0.03 | 6 |

FTIR analysis of the resultant amorphous carbon only films (See, FIG. 2) revealed that the absorptions at 2900-2700 cm⁻¹, which were attributed to sp³ C—H, and the absorption at 1440 cm⁻¹ and 1370 cm⁻¹, which were attributed to sp³ CH₃ bending, increased dramatically relative to the sp² C═C stretching vibration at 1600 cm⁴ as the deposition temperature was decreased from 550° C. to 480° C. to 400° C. with all other deposition conditions held constant. The lower deposition temperature contributed to incomplete fragmentation of the carbon precursor, which in turn, resulted in higher percentage of CH hydrocarbon bonding in the final amorphous carbon only film. This effect is captured in the normalized hydrocarbon content value.

The increased hydrocarbon content lowered the extinction coefficient (k) of the amorphous carbon only films and resulted in a higher level of outgassing during laser and flash anneals. Higher extinction coefficient (k) is desirable because it results in greater absorbance and minimizes reflectance variations from the underlying substrate.

The applicants have also discovered that the overall higher hydrocarbon content adversely affects the optical properties of the film, and lowers the extinction coefficient (k), and the emissivity of the film making the film more transparent to the impinging laser.

In one aspect of the present invention, an improved electromagnetic radiation absorber is provided that comprises, consists essentially of, or consists of, an amorphous carbonitride (ACN) film having an extinction coefficient of greater than 0.15, and an emissivity of greater than 0.8. In some embodiments of the invention, the amorphous carbonitride film can be characterized as having a low hydrocarbon content as observed by FTIR. ACN films having the low hydrocarbon content, minimize outgassing during a subsequent laser annealing or flash annealing process. The ACN films can be easily removed after annealing by plasma oxygen ashing. Such an amorphous carbonitride film represents an improvement over conventionally used amorphous carbon only films.

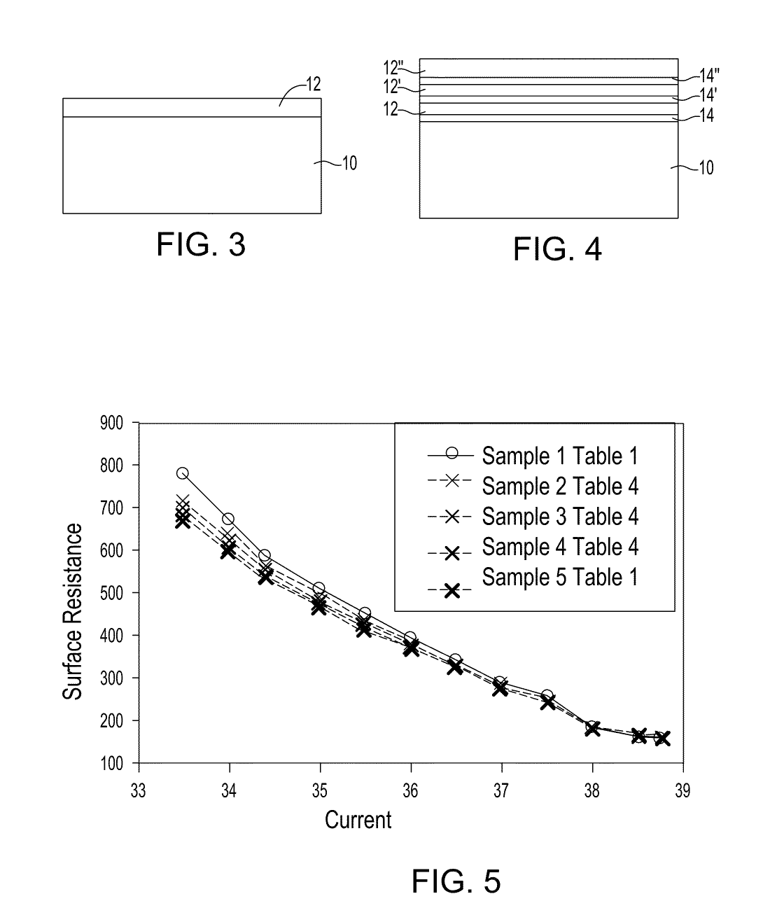

Reference is now made to FIG. 3 which is a pictorial representation of one embodiment of the invention in which an amorphous carbonitride film 12 having the aforementioned properties, i.e., extinction coefficient, emissivity and optionally low hydrocarbon content, is formed on a surface of a substrate 10. The substrate 10 can be a semiconductor material, a dielectric material, a conductive material or any multilayered combination thereof. In one embodiment, the substrate 10 is a multilayered combination of at least a semiconductor material, a dielectric material and a conductive material, wherein the semiconductor material is a semiconductor substrate, the dielectric material is a patterned gate dielectric and the conductive material is a patterned gate electrode that is located atop the patterned gate electrode.

When a semiconductor material is employed as an element of substrate 10, the semiconductor material can include, but is not limited to Si, Ge, SiGe, SiC, SiGeC, GaAs, GaN, InAs, InP and all other III/V or II/VI compound semiconductors. The semiconductor material may also comprise an organic semiconductor or a layered semiconductor such, as for, example, Si/SiGe, a silicon-on-insulator (SOI), a SiGe-on-insulator (SGOI) or a germanium-on-insulator (GOI). In some embodiments of the invention, the semiconductor material is a Si-containing semiconductor material that includes silicon. The semiconductor material may be doped, undoped or contain doped and undoped regions therein. The semiconductor material can include a single crystal orientation or it may include at least two coplanar surface regions that have different crystal orientations (the latter semiconductor material can be referred to as a hybrid orientation substrate). The semiconductor material can be process utilized techniques well known to those skilled in the art to include one or more well regions, and/or one or more isolation regions. The semiconductor material can also be processed utilizing techniques well known to those skilled in the art to include one or more semiconductor devices atop an uppermost surface of the semiconductor substrate.

When a dielectric material is employed as an element of substrate 10, the dielectric material can include an organic insulator, an inorganic insulator or any combination thereof including multilayers. In one embodiment, the dielectric material is an oxide, a nitride, and/or an oxynitride. In yet another embodiment, the dielectric material has a dielectric constant, as measured in a vacuum of equal to, or greater than, the dielectric constant of silicon oxide.

When a conductive material is employed as an element of substrate 10, the conductive material can include, for example, a doped Si-containing material, an elemental metal, an alloy of an elemental metal, a metal silicide, a metal nitride or any combination thereof including multilayers.

It is observed that the semiconductor material, dielectric material and/or conductive material may be part of a device or structure, which may be discrete or interconnected.

As stated above, and as illustrated in FIG. 3, an amorphous carbonitride film 12 is formed atop the substrate 10. The amorphous carbonitride film 12 that is formed has an extinction coefficient of greater than 0.15. Typically, the amorphous carbonitride film 12 has an extinction coefficient from 0.15 to 0.6, more typically the amorphous carbonitride film 12 has an extinction coefficient from 0.15 to 0.4.

The amorphous carbonitride film 12 also has an emissivity of greater than 0.8. Typically, the amorphous carbonitride film 12 has an emissivity from 0.8 to 0.95. More typically, film 12 has an emissivity from 0.85 to 0.92.

A further feature of the amorphous carbonitride film 12 is that it has a minimum hydrocarbon content as measured by FTIR. By “a minimum of hydrocarbon content as observed by FTIR” it is meant a normalized hydrocarbon content less than 3 as defined by integrating under the C—H stretching peak in the FTIR spectra from 3170-2750 cm⁻¹ and dividing the integrated peak area by the film thickness in microns.

The thickness of the amorphous carbonitride film 12 that is formed may vary depending on the conditions in which the amorphous carbonitride film 12 is deposition. Typically, the amorphous carbonitride film 12 that is formed atop the substrate 10 has a thickness from 50 nm to 5000 nm, with a thickness from 100 nm to 500 nm being more typical. Other thicknesses can also be employed so long as the thickness does not interfere with the amorphous carbonitride film being employed as an absorbing layer for exposures to various wavelengths of electromagnetic radiation including, for an example, an exposure wavelength between 190 nm and 1000 nm.

The amorphous carbonitride film 12 can be formed utilizing any low temperature (e.g., of less than, or equal to, 450° C.) deposition process. Suitable examples of low temperature deposition processes that can be used in forming the amorphous carbonitride film 12 include, but are not limited to chemical vapor deposition (CVD) and plasma enhanced chemical vapor deposition (PECVD). In one embodiment of the invention, the amorphous carbonitride film 12 is formed utilizing a low temperature PECVD process.

As stated above, any deposition process can be used in forming the amorphous carbonitride film 12 having the above properties so long as the deposition temperature is less than, or equal to, 450° C. In one embodiment of the invention, the amorphous carbonitride film 12 having the above properties can be produced using a deposition temperature from 250° C. to 450° C. In yet another embodiment of the invention, the amorphous carbonitride film 12 having the above properties can be produced using a deposition temperature from 350° C. to 400° C.

In one embodiment of the invention, the amorphous carbonitride film 12 having the above properties can be produced using a combination of at least a carbon precursor source, and a nitrogen source. An oxidant is also typically, but not necessarily always, employed to facilitate decomposition, fragmentation and hydrogen removal. Such a combination of gases can be referred to herein as a reactant gas mixture. The reactant gas mixture may further include an inert gas such as helium or argon. The inert gas may be introduced as a separate component of the reactant gas mixture or it can be present within at least one of the carbon precursor source, the nitrogen source and the oxidant.

In some embodiments of the invention, the amorphous carbonitride film 12 having the above properties can be produced using a single carbonitride precursor that includes both carbon and nitrogen in the molecule. An oxidant is also typically, but not necessarily always, employed in this embodiment of the invention as well.

The carbon precursor source that can be employed in the invention is selected from alkanes, alkenes, alkynes and mixtures thereof. The carbon precursor sources may be linear, branched, and/or cyclic. In one embodiment of the invention, the carbon precursor sources have a minimal C/H ratio. By “minimal C/H ratio” it is meant less than 3 hydrogens for every carbon atom in the precursor.

The term “alkane” denotes a chemical compound that consists only of the elements carbon and hydrogen (i.e., hydrocarbons), wherein these atoms are linked together exclusively by single bonds (i.e., they are saturated compounds). In one embodiment of the invention, the alkane includes from 1 to 22, typically from 1 to 16, more typically, from 1 to 12 carbon atoms.

The term “alkene” denotes an unsaturated chemical compound containing at least one carbon-to-carbon double bond, In one embodiment, the alkene is an acyclic alkene, with only one double bond and no other functional groups. In such an embodiment, the acylic alkene forms a homologous series of hydrocarbons with the general formula CₙH₂ₙ, wherein n is an integer from 2 to 22, typically 2 to 16, more typically 2 to 12 carbon atoms.

The term “alkyne” denotes a hydrocarbon that has a triple bond between two carbon atoms, with the formula CₙH₂ₙ₋₂, wherein n is an integer from 2 to 22, typically 2 to 16, more typically 2 to 12 carbon atoms. Alkynes are traditionally known as acetylenes.

Some examples of typical carbon precursor sources that can be employed in forming the amorphous carbonitride film 12 include, but are not limited to ethylene, propylene, butene, acetylene, and/or methyl acetylene. In one embodiment, propylene (C₃H₆) is employed as the carbon precursor source.

The nitrogen source that can be employed in forming the amorphous carbonitride film 12 can be selected from nitriding sources including, but not limited to nitrogen, ammonia, amines, azides, and/or hydrazines. In one embodiment of the invention, nitrogen (N₂) and/or ammonium (NH₃) is employed as the nitrogen source. The oxidant that can be employed in forming the amorphous carbonitride film 12 can be selected from oxidizing sources including oxygen, nitrous oxide, water, and/or ozone. In one embodiment of the invention, oxygen is employed as the oxidant.

Although any combination of carbon precursor source, nitrogen source and oxidant can be employed in forming the amorphous carbonitride film 12, one embodiment of the present invention employs propylene (C₃H₆) as the carbon precursor source, nitrogen (N₂) or ammonium (NH₃) as the nitrogen source, and oxygen (O₂) as the oxidant. Such a reactant gas mixture can be used as is or diluted with an inert gas such as helium or argon.

In one embodiment of the present invention, as mentioned above, a single carbonitride precursor that includes both carbon and nitrogen in the molecule can be used to form the amorphous carbonitride film 12. One example of such a single carbonitride precursor that can be employed in the present invention is acetonitrile (C□N). Other single carbonitride precursors beside acetonitrile can be used as long as the precursor includes carbon and nitrogen atoms therein. When a single carbonitride precursor is employed, an oxidant, as described above can also be used. The single carbonitride precursor can be used as is or diluted with an inert gas such as helium or argon. Other potential single carbonitride precursors include heterocyclic compounds such as pyrrole, imidazole, pyrazole, pyridine, pyrazine, pyrimidine, pyridazine, pyrazinyl, imidazolyl, pyrimidinyl, piperazine, triazine, amines such as methylamine, diamine ethane, diamine methane, aminoethane, aminopropane, azo, hydrzo, dimethylhydrazine, alkylazo compounds such as diethyldiazene, and amidines including acetamidine.

The gases may be introduced separately into a reactor chamber of a deposition tool, or some, or all of the gases may be admixed prior to being introduced into a reactor chamber of a deposition tool. Typically, the various gases are admixed in a mixing system prior to being introduced into the reactor chamber of a deposition tool. The reactor chamber of the deposition tool typically includes a substrate holder in which the substrate 10 is positioned within the reactor chamber. The distance of the substrate holder from the nozzle (or nozzles or showerhead) in which the reactant gas mixture (or gasses) is (are) introduced may vary within typical ranges well known to those skilled in the art. Typically, the substrate holder and hence substrate 10 is positioned a distance from 600 mils to 200 mils from the nozzle (or nozzles).

In addition, the gases may be introduced in a deposition tool in different stochiometries. In some embodiments of the invention, the carbon source may be introduced at a flow rate between 50 sccm and 2000 sccm, the nitrogen source may be introduced at a flow rate between 10 sccm and 50000 sccm, and the oxidant may be introduced at a flow rate between 10 sccm and 500 sccm. In another embodiment of the invention, the carbon source may be introduced at a flow rate between 50 sccm and 5000 sccm, the nitrogen source may be introduced at a flow rate between 10 sccm and 5000 sccm, and the oxidant may be introduced at a rate between 1 sccm and 1000 sccm. The inert gas may be introduced at a flow rate from 50 sccm to 50000 sccm.

In some further embodiments of the invention, the process pressure used in forming the amorphous carbonitride film 12 can be varied from 1 torr to 8 torr. In yet another embodiment of the invention, the substrate temperature during the deposition process can be fixed at 400° C. or 350° C. In an even further embodiment of the invention, the plasma can be generated using either a low frequency radio frequency (LFRF) plasma source at 100 MHz or a high frequency radio frequency HFRF plasma source at 13.56 GHz. The process pressure, substrate temperature and power used in generating the plasma are exemplary and other conditions are possible provided the selected conditions are capable of forming an amorphous carbonitride film having an extinction coefficient of greater than 0.15, an emissivity of greater than 0.8 and a minimum of hydrocarbon content.

In one embodiment of the invention, the amorphous carbonitride film 12 is formed by positioning substrate 10 within a parallel plate plasma enhanced chemical vapor deposition chamber. A reactant gas mixture, as defined above, is then introduced into the reactor chamber and thereafter an amorphous carbonitride film 12 having an extinction coefficient of greater than 0.15, an emissivity of greater than 0.8 and a minimum of hydrocarbon is formed.

Reference is now made to FIG. 4 which is a pictorial representation (through a cross sectional view) depicting a structure including a substrate 10 having an adhesion promoting layer 14, and an amorphous carbonitride film 12 formed thereon in accordance with an embodiment of the invention. It is observed that another adhesion promoting layer 14′ and another amorphous carbonitride film 12′ can be formed atop the amorphous carbonitride film 12 to form a layered structure as shown in FIG. 4. The structure in FIG. 4 may yet further include yet another adhesion promoter layer 14″ and yet another amorphous carbonitride film 12″ formed therein. The substrate 10 and amorphous carbonitride films 12, 12′ and 12″ are the same as those described above in FIG. 3. The adhesion promoting layers 14, 14′ and 14″ are thin layers typically from 1 nm to 20 nm in thickness. The presence of the adhesion promoting layer improves the adhesion of the amorphous carbonitride film to the substrate and to various layers within the structure. Such films including the combination of the amorphous carbonitride films and the adhesion promoting layers may be referred to as a gradient or layered amorphous carbonitride film. Typically, the adhesion promoting layers have a thickness that is less than the thickness of the amorphous carbonitride films.

The amorphous carbonitride films described hereinabove can be used for absorbing electromagnetic radiation having one or more wavelengths between 190 nm and 1000 nm. The amorphous carbonitride films described hereinabove can also be used in conjunction with conventional laser anneals to improve the heating uniformity across a plurality of surfaces.

The following examples are provided to illustrate the formation of amorphous carbonitride films having an extinction coefficient (k) of greater than 0.15, an emissivity of greater than 0.8 and a minimum of hydrocarbon. The following examples illustrate some advantages and/or improvements that can be obtained from such amorphous carbonitride films.

### Example 1

Amorphous carbonitride films of the current invention were deposited onto an oxide coated silicon substrate using the following conditions: 400° C. deposition temperature, 500 watts LFRF, 220 mils, and 3 torr pressure. Propylene (C₃H₆) was fixed at 1000 sccm, while the reactant gases (i.e., nitrogen and ammonia), and the oxidant (N₂O) were varied as detailed in Table 2. Refractive index (n) and extinction coefficient (k) were measured using an n&k tool.

TABLE 2
Amorphous carbonitride deposition conditions

| | | Tem- | | | | | | |
|---|---|---|---|---|---|---|---|---|
| | Pres- | per- | | | | | | |
| Sam- | sure | ature | C₃H₆ | N₂O | N₂ | NH₃ | He | |
| ple | (torr) | (° C.) | (sccm) | (sccm) | (sccm) | (sccm) | (sccm) | k |
| 1 | 3 | 400 | 1000 | 80 | 0 | 0 | 0 | 0.15 |
| 2 | 3 | 400 | 1000 | 80 | 5000 | 70 | 0 | 0.19 |
| 3 | 3 | 400 | 1000 | 200 | 5000 | 70 | 0 | 0.30 |

As summarized in the Table 2, for Sample 1 deposited from propylene and N₂O only, the extinction coefficient was 0.15. However, by formation of the carbonitride in Sample 2 of this example with the addition of nitrogen, and ammonia the extinction coefficient, k was increased to 0.19. In Sample 3 of this example an additional increase in N₂O increased k to 0.3. The oxidant, N₂O in this case was essential in increasing k.

### Example 2

Amorphous carbonitride films of the current invention were deposited onto an oxide coated silicon substrate with deposition conditions as summarized in Table 3 at 400° C. Propylene (C₃H₆) was fixed at 500 sccm, oxygen was fixed at 50 sccm, mil spacing was fixed at 220 mils and pressure was fixed at 4 torr. Refractive index (n) and extinction coefficient (k) were measured using an n&k tool. Oxygen was used as the oxidant as shown in Table 3.

TABLE 3
Deposition Conditions

| | | | | | | | | | CH |
|---|---|---|---|---|---|---|---|---|---|
| | | | | | | | | | Peak |
| | | | | | | | | | area/ |
| Temp. | HFRF | LFRF | Press. | C₃H₆ | O₂ | N₂ | NH₃ | | thick |
| (° C.) | (watts) | (watts) | (torr) | (sccm) | (sccm) | (sccm) | (sccm) | k | (μm) |
| 400 | 1000 | 0 | 4 | 500 | 50 | 5000 | 70 | 0.25 | 1.3 |
| 400 | 0 | 500 | 4 | 500 | 50 | 5000 | 70 | 0.25 | 1.7 |
| 400 | 0 | 500 | 4 | 500 | 50 | 10000 | 70 | 0.29 | 0.6 |

Switching from HFRF to LFRF plasma power resulted in a halving of the normalized hydrocarbon content as observed by FTIR. The normalized hydrocarbon content is defined by integrating under the C—H stretching peak in the FTIR spectra from 3170-2750 cm⁻¹ and dividing the integrated peak area by the film thickness in microns.

### Example 3

Thin layers of amorphous carbonitride (ACN) films were deposited on top of each other with varying plasma frequencies to achieve thicker films. Such a structure is shown, for example, in FIG. 4. These layers were addressed as adhesion promoting layers in this disclosure. This was done to avoid the delamination of a thick film due to inherent intrinsic compressive stress. Five ACN films were deposited at 400° C. and 220 mils. The propylene and oxygen were fixed at 500 sccm and 10 sccm respectively. A thin adhesion promoting layer (ACN1 time: 10 sec deposition time) at 1000 W HFRF (13.56 MHz) was deposited initially and in between thicker ACN layers (ACN2 time: 60 sec deposition time) in order to achieve a thicker film with a higher k and emissivity. The substrates were then annealed using a laser at 1350° C. The emissivity of the substrates were measured and listed in the Table 4, with other details.

TABLE 4
Deposition Conditions

| | | ACN1 | ACN1 | ACN1 | ACN2 | ACN2 | | | | |
|---|---|---|---|---|---|---|---|---|---|---|
| | Pressure | N₂ | NH₃ | HFRF | N₂ | NH₃ | ACN2 | | 3 cycle | 3 cycle |
| Sample | (torr) | (sccm) | (sccm) | (watts) | (sccm) | (sccm) | LFRF | cycles | emissivity | k |
| 1 | 4 | 2500 | 100 | 1000 | 1000 | 300 | 600 | 3 | 0.904 | 0.294 |
| 2 | 4 | 2500 | 300 | 1000 | 2500 | 100 | 600 | 3 | 0.826 | 0.261 |
| 3 | 4 | 2500 | 10 | 1000 | 5000 | 10 | 600 | 3 | 0.887 | 0.356 |
| 4 | 6 | 5000 | 10 | 1000 | 5000 | 70 | 600 | 3 | 0.861 | 0.253 |
| 5 | 6 | 5000 | 70 | 1000 | 5000 | 100 | 600 | 3 | 0.904 | 0.327 |

Surface resistance measurements were taken with the last four conditions. As shown in FIG. 5, the surface resistance of the ACN results was better than or comparable to 550° C. ACL films. ACN films can be removed using a down stream oxygen plasma ash technique followed by sulfuric nitric acid dip. The Rₛ measurements performed on 400° C. ACN films are plotted together with the existing 550° C. ACL film in FIG. 5.

### Example 4

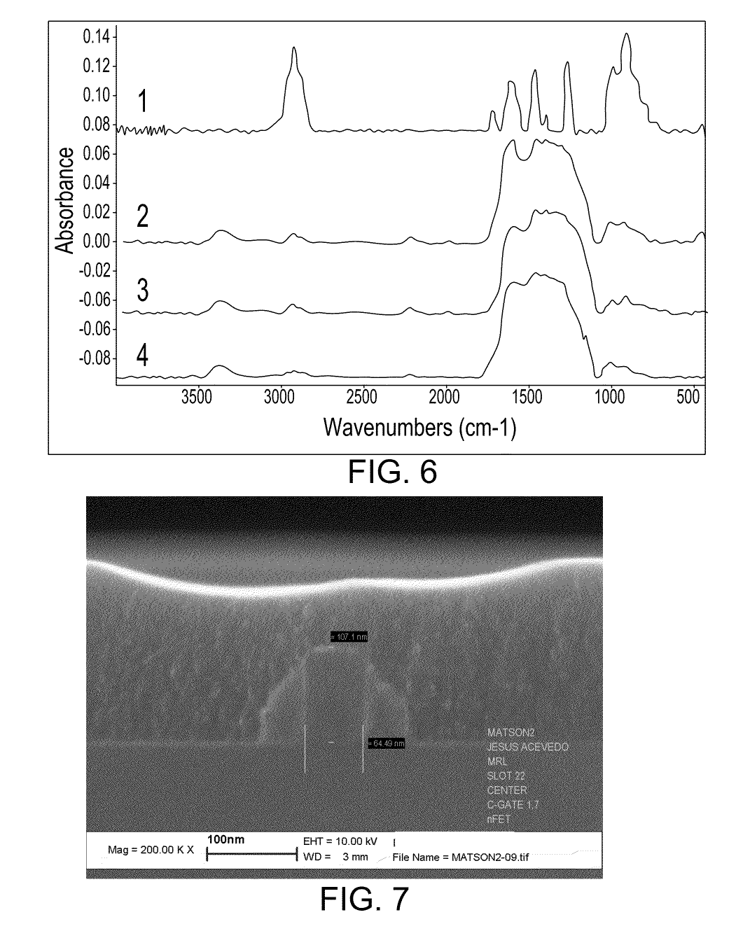

As shown in FIG. 6, addition of nitrogen is critical in forming the amorphous carbonitride film. The FTIR spectra of Sample 1 of this example deposited at 350° C. without nitrogen or ammonia is consistent with formation of an amorphous carbon film. Sample 1 of this example differs from the films depicted in FIG. 2. The addition of oxygen during deposition resulted in the formation of C═O species in the film as evidenced by the FTIR absorption at 1700 cm⁻¹. Film properties are summarized in Table 5. Without N₂ or ammonia in the recipe the resultant film Sample 1 of this example had an extinction coefficient of 0.13 and a normalized hydrocarbon content of 3. Formation of the carbonitride by addition of ammonia and/or ammonia during deposition resulted in increased k>0.2 and reduction of the normalized hydrocarbon content to 1.

TABLE 5
Deposition Conditions

| | | | | | | | | | | CH peak |
|---|---|---|---|---|---|---|---|---|---|---|
| | Temperature | Pressure | LFRF | C₃H₆ | O₂ | N₂ | NH₃ | He | | area/thickness |
| Sample | (° C.) | (torr) | (watts) | (sccm) | (sccm) | (sccm) | (sccm) | (sccm) | k | μm |
| 1 | 350 | 8 | 500 | 350 | 100 | 0 | 0 | 5000 | 0.13 | 3 |
| 2 | 350 | 8 | 500 | 350 | 100 | 0 | 300 | 5000 | 0.21 | 1 |
| 3 | 350 | 8 | 500 | 350 | 100 | 2500 | 0 | 5000 | 0.27 | 1 |
| 4 | 350 | 8 | 500 | 350 | 100 | 2500 | 300 | 5000 | 0.32 | 1 |

### Example 5

The effect of He dilution on k was also observed, and it was determined that by increasing the He dilution resulted in an ACN film having a larger k. In this example, the deposition temperature was 350° C., 220 mil, the pressure was 4 torr. Table 6 includes the other conditions used in this example. As shown in the table by increasing He flow k can be increased.

TABLE 6
Deposition Conditions

| | | | | | | | | | | CH peak |
|---|---|---|---|---|---|---|---|---|---|---|
| | Temperature | Pressure | LFRF | C₃H₆ | O₂ | N₂ | NH₃ | He | | area/thickness |
| Sample | (° C.) | (torr) | (watts) | (sccm) | (sccm) | (sccm) | (sccm) | (sccm) | k | μm |
| 1 | 350 | 4 | 500 | 500 | 10 | 2500 | 300 | 1000 | 0.15 | 1.5 |
| 2 | 350 | 4 | 500 | 500 | 10 | 2500 | 300 | 3000 | 0.24 | 1.4 |
| 3 | 350 | 4 | 500 | 500 | 10 | 2500 | 300 | 5000 | 0.26 | 0.9 |

### Example 6

Amorphous carbonitride films of this invention were deposited at 350° C. with varying amounts of oxygen and other conditions as mentioned in this example. The carbon precursor, i.e., C₃H₆, was flowed at 350 sccm, N₂ at 2500 sccm, NH₃ at 300 sccm, He at 5000 sccm and a LFRF power of 500 watts (approximately 100 MHz) and a pressure of 4 ton were employed. The optical properties measured on the films indicated that extinction coefficient of such films were very high. See Table 7.

TABLE 7
Deposition Conditions

| | Temperature | Pressure | LFRF | C₃H₆ | O₂ | N₂ | NH₃ | He | |
|---|---|---|---|---|---|---|---|---|---|
| Sample | (° C.) | (torr) | (watts | (sccm) | (sccm) | (sccm) | (sccm) | (sccm) | k |
| 1 | 350 | 4 | 500 | 350 | 10 | 2500 | 300 | 5000 | 0.36 |
| 2 | 350 | 4 | 500 | 350 | 50 | 2500 | 300 | 5000 | 0.39 |
| 3 | 350 | 4 | 500 | 350 | 100 | 2500 | 300 | 5000 | 0.32 |

These films were then subjected to flash lamp annealing and SEM micrographs were obtained on ACN films after flash anneal applications. It was evident from the SEM micrographs that ACN films deposited at 350° C. survived the flash lamp annealing and also they are very conformal with intact microstructure after annealing. One such SEM micrograph is shown, for example, in FIG. 7. After flash anneal, thickness, n and k are relatively unchanged after anneal indicative that the films are very stable and less prone to outgassing at higher temperatures.

### Example 7

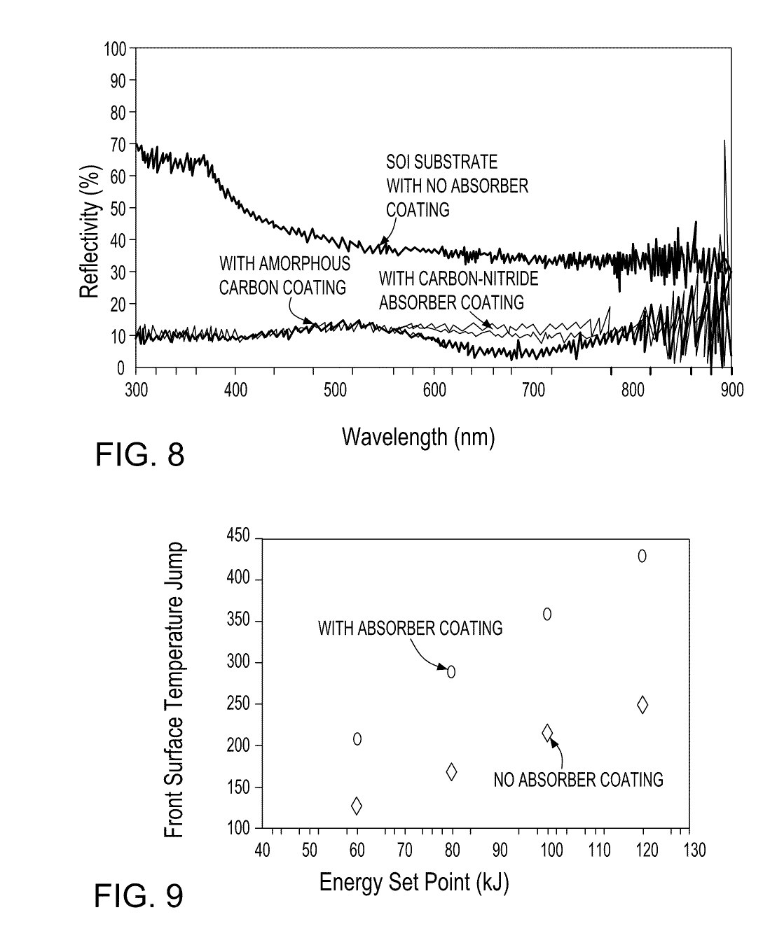

As shown in FIG. 8, for semiconductor-on-insulator (SOI) technology, the SOI substrate without an absorber layer was highly reflective to light (wavelength between 300 nm to 400 nm) generated by an arc-lamp from a high temperature millisecond flash anneal tool. As shown in FIG. 8, after coating an SOI substrate with an amorphous carbon layer from the prior art (Sample 1, Table 1) and an amorphous carbonitride absorber layer of this invention (Sample 2, Table 7) reflectivity from the SOI substrate was substantially reduced from 40% for uncoated SOI substrate to 10%. The carbonitride absorber layer deposited at 350° C. of this invention (Sample 2, Table 7) was as effective as the amorphous carbon layer deposited at 550° C. in reducing reflectivity of the SOI substrate.

Reduction in reflectivity enables higher front surface temperatures during flash anneal which, in turn, enables lower backside substrate temperatures to minimize dopant movement, source/drain junction profile broadening and increased junction depth. Shown in FIG. 9, for each energy set point of the flash anneal lamps a substrate coated with an absorber layer had a 100-200° C. increased front surface temperature than an uncoated substrate. Thus, for a given maximum available power from the arc-lamp of the flash anneal tool, the high reflectance from SOI substrate severely limits the temperature jump for the SOI device substrate during a high temperature mill-second flash anneal.

Flash anneal and laser spike anneals have been introduced to activate dopants in milliseconds. Boron dopant deactivation is proposed to be due to the formation of inactive boron-interstitial clusters (BICs) as a result of the release of silicon interstitials from the end-of-range (EOR) defects upon annealing. Carbon atoms are reported to be an effective sink for silicon interstitials and that extended defect levels are reduced or eliminated with increasing carbon dose. See, Chyiu Hyia Poon, JOURNAL OF APPLIED PHYSICS 103, 084906 _{—}2008. In this example, the carbonitride absorber layer deposited at 350° C. of this invention (Sample 2, Table 7) was employed as an efficient absorber coating for a flash anneal so that the arc-lamp light from the flash anneal is efficiently absorbed and subsequently increased the temperature jump for the SOI device substrate to achieve improved C substitution in SiC source/drain and to maximize junction activation for 22 nm CMOS technology devices and beyond.

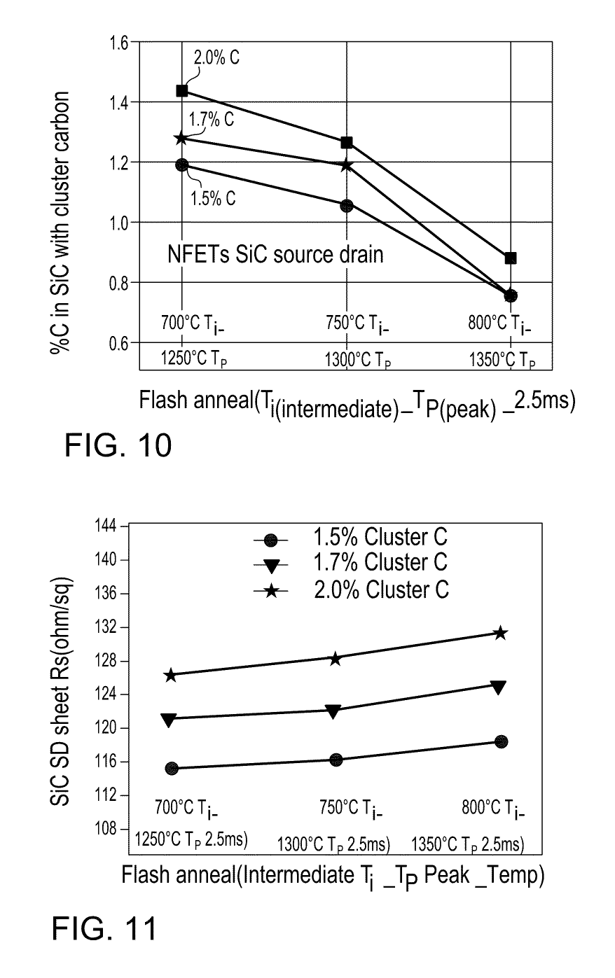

Shown in FIG. 10, is the dependence of improved C substitution in SiC source/drain regions on peak and intermediate temperature during a flash activation anneal. The substrate was heated to an intermediate temperature of 700° C. and the lamps were flashed to spike the peak temperature to at least 1250° C. A % C content of 1.2-1.5% was achieved in the SiC dependant on the starting implanted carbon concentration. At a higher intermediate temperature of 800° C., the % C content was reduced to 0.7-0.9%. The measured sheet resistance of the source/drain contact shown in FIG. 11 with intermediate temperature of 700° C. and peak temperature of 1250° C. was 114-126 ohm/square with resistance increasing slightly from 114 to 16 ohm/square with increasing carbon concentration.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. An electromagnetic absorber comprising an amorphous carbonitride film having an extinction coefficient of greater than 0.2 and an emissivity of greater than 0.8.

2. The electromagnetic absorber of claim 1 wherein said amorphous carbonitride film has a normalized hydrocarbon content less than 3 as defined by integrating under a C—H stretching peak in a FTIR spectra from 3170-2750 cm⁻³ and dividing the integrated peak area by film thickness in microns.

3. The electromagnetic absorber of claim 1 wherein said amorphous carbonitride film includes a gradient carbonitride film having an adhesion promoting layer located on a surface thereof.

4. The electromagnetic absorber of claim 1 wherein said amorphous carbonitride film absorbs electromagnetic radiation having at least one wavelength between 190 nm and 1000 nm.

5. A structure comprising an amorphous carbonitride film disposed on an upper surface of a substrate, wherein said amorphous carbonitride film has an extinction coefficient greater than 0.2 and an emissivity of greater than 0.8.

6. The structure of claim 5 wherein said amorphous carbonitride film has a normalized hydrocarbon content less than 3 as defined by integrating under a C—H stretching peak in a FTIR spectra from 3170-2750 cm⁻¹ and dividing the integrated peak area by film thickness in microns.

7. The structure of claim 5 wherein said amorphous carbonitride film includes a gradient carbonitride film having an adhesion promoting layer located on a surface thereof.

8. The structure of claim 5 wherein said amorphous carbonitride film absorbs electromagnetic radiation having at least one wavelength between 190 nm and 1000 nm.

9. The structure of claim 5 wherein said substrate includes a semiconductor material, a dielectric material, a conductive material or any multilayered combination thereof.

10. A method comprising:
depositing an amorphous carbonitride film on an upper surface of a substrate at a deposition temperature of less than, or equal to 450° C., wherein said amorphous carbonitride film has an extinction coefficient of greater than 0.2 and an emissivity of greater than 0.8.

11. The method of claim 10 wherein said depositing comprises:
positioning said substrate within a reactor chamber of a deposition apparatus;
introducing a reactant gas mixture including at least a carbon precursor source, a nitrogen source, and an oxidant into said reactor chamber; and
generating a plasma from said reactant gas mixture.

12. The method of claim 11 wherein said carbon precursor source includes an alkane, an alkene, an alkyne or mixtures thereof, said nitrogen source includes nitrogen, ammonia, an amine, an azides, and/or a hydrazine, and said oxidant includes oxygen, nitrous oxide, water, and/or ozone.

13. The method of claim 11 wherein said reactant gas mixture further comprises an inert gas including helium and argon, said inert gas being introduced at a flow rate from 500 sccm to 50000 sccm.

14. The method of claim 10 wherein said generating the plasma includes selecting a LFRF or HFRF plasma source at 100 MHz or 13.56 GHz, respectively.

15. The method of claim 10 wherein said generating the plasma includes first depositing an adhesion promoting layer, and second depositing the amorphous carbonitride film on the adhesion promoting layer.

16. The method of claim 10 wherein said depositing comprises:
positioning said substrate within a reactor chamber of a deposition apparatus;
introducing a reactant gas mixture including at least a carbon precursor source, and a nitrogen source, into said reactor chamber; and
generating a plasma from said reactant gas mixture.

17. The method of claim 16 wherein said carbon precursor source includes an alkane, an alkene, an alkyne or mixtures thereof, and said nitrogen source includes nitrogen, ammonia, an amine, an azide, and/or a hydrazine.

18. The method of claim 16 wherein said reactant gas mixture further comprises an inert gas including helium and argon, said inert gas being introduced at a flow rate from 500 sccm to 50000 sccm.

19. The method of claim 16 wherein said generating the plasma includes selecting a LFRF or HFRF plasma source at 100 MHz or 13.56 GHz, respectively.

20. The method of claim 10 wherein said depositing comprises:
positioning said substrate within a reactor chamber of a deposition apparatus;
introducing a reactant gas mixture including at least a precursor which contains carbon and nitrogen; and
generating a plasma from said reactant gas mixture.

21. The method of claim 20 wherein said carbon and nitrogen precursor source includes an carbon and nitrogen containing heterocyclic compounds, amines, alkylazo compounds, acetonitile and amidines.

22. The method of claim 20 wherein said reactant gas mixture further comprises an inert gas including helium and argon, said inert gas being introduced at a flow rate from 500 sccm to 50000 sccm.

23. The method of claim 20 wherein said reactant gas mixture further comprises an oxidizing gas includes oxygen, nitrous oxide, water, and/or ozone, said oxidizing gas being introduced at a flow rate from 500 sccm to 50000 sccm.

24. The method of claim 20 wherein said generating the plasma includes selecting a LFRF or HFRF plasma source at 100 MHz or 13.56 GHz, respectively.

25. The method of claim 10 further comprising performing flash annealing or laser annealing to activate a doped source region and a doped drain region within said substrate.
